(19) United States
(12) Patent Application Publication
(10) Pub. No.: US 2026/0286501 A1
(43) Pub. Date: Sep. 24, 2026

(54) YTTRIUM-BASED PROTECTIVE FILM, METHOD FOR PRODUCING SAME, AND MEMBER

(71) Applicants: AGC Inc., Tokyo (JP); TSUBASA SCIENCE CORPORATION, Yokohama-shi (JP)

(72) Inventors: Naoto KIHARA, Tokyo (JP); Kotaro ISHITA, Tokyo (JP); Rui MATSUMURA, Tokyo (JP); Shuhei OGAWA, Tokyo (JP); Michio ISHIKAWA, Kanagawa (JP); Michio TANIMURA, Kanagawa (JP); Hidekazu OKADA, Kanagawa (JP)

(73) Assignees: AGC Inc., Tokyo (JP); TSUBASA SCIENCE CORPORATION, Yokohama-shi (JP)

(21) Appl. No.: 19/649,295

(22) Filed: Apr. 16, 2026

Related U.S. Application Data
(63) Continuation of application No. PCT/JP2024/037377, filed on Oct. 21, 2024.

(30) Foreign Application Priority Data
Oct. 26, 2023 (JP) 2023-184119

(51) Int. Cl. C23C 14/24; C23C 14/06

(52) U.S. Cl. CPC C23C 14/24; C23C 14/0694

(57) ABSTRACT

An yttrium-based protective film has a porosity of less than 1.5 volume %, a Young's modulus of 100.00 GPa or more, and a Vickers hardness of 8.50 GPa or more. A method for producing the yttrium-based protective film includes evaporating an evaporation source and depositing the evaporation source onto a substrate while irradiating with ions of at least one element selected from the group consisting of oxygen, argon, neon, krypton, and xenon from an ion gun in a vacuum. Y₂O₃ or a combination of Y₂O₃ and YF₃ is used as the evaporation source.

### CROSS-REFERENCE TO RELATED APPLICATIONS

This is a bypass continuation of International Application No. PCT/JP2024/037377 filed on Oct. 21, 2024, and claims priority from Japanese Patent Application No. 2023-184119 filed on Oct. 26, 2023, the entire content of which is incorporated herein by reference.

### TECHNICAL FIELD

The present invention relates to an yttrium-based protective film, a method for producing the yttrium-based protective film, and a member.

### BACKGROUND ART

When a semiconductor device is produced, for example, a surface of a semiconductor substrate (silicon wafer) is microfabricated by dry etching using halogen-based gas plasmas in a chamber, and the chamber from which the semiconductor substrate is taken out after the dry etching is cleaned using oxygen gas plasmas.

At this time, the member exposed to the plasma in the chamber may corrode, and portions of the corroded member may detach as particles. The detached particles adhere to the semiconductor substrate and may become foreign matter that causes circuit defects.

In the related art, a protective film (yttrium-based protective film) containing yttrium oxides or yttrium oxyfluorides has been known as a protective film for protecting the member exposed to plasmas.

Patent Literature 1 discloses a thermal sprayed coating that is formed by thermal spraying and contains yttrium oxides or yttrium oxyfluorides.
Patent Literature 1: JP2018-76546A

### SUMMARY OF INVENTION

The present inventors have studied and found that the yttrium-based protective film in the related art may have insufficient plasma resistance (corrosion resistance against plasmas).

The present invention has been made in view of the above points, and an object thereof is to provide an yttrium-based protective film having excellent plasma resistance.

As a result of intensive studies, the present inventors have found that the above objective can be achieved by adopting the following configuration, and have completed the present invention.

That is, the present invention provides the following [1] to [30].
[1] An yttrium-based protective film having a porosity of less than 1.5 volume %, a Young's modulus of 100.00 GPa or more, and a Vickers hardness of 8.50 GPa or more.
[2] The yttrium-based protective film according to [1], in which a ratio Young's modulus/Vickers hardness is 16.5 or less.
[3] The yttrium-based protective film according to [1] or [2], including 0.10 atom % to 3.00 atom % of argon.
[4] The yttrium-based protective film according to any one of [1] to [3], including 5 atom % or more of yttrium.
[5] The yttrium-based protective film according to any one of [1] to [4], including 25 atom % to 65 atom % of fluorine.
[6] The yttrium-based protective film according to any one of [1] to [5], in which a F/O ratio, which is a ratio of a fluorine content to an oxygen content, is less than 2.80, in which units of the fluorine content and the oxygen content are both atom %.
[7] The yttrium-based protective film according to any one of [1] to [6], in which a peak intensity ratio of Y₅O₄F₇ in an X-ray diffraction pattern is 60% or more.
[8] The yttrium-based protective film according to any one of [1] to [7], having a crystallite size of 5 nm to 30 nm.
[9] The yttrium-based protective film according to any one of [1] to [8], having a thickness of 0.01 μm to 30.0 μm.
[10]A member including a substrate and the yttrium-based protective film according to any one of [1] to [9].
[11] The member according to [10],
in which the substrate includes, as a deposition surface, at least a first deposition surface and a second deposition surface different from the first deposition surface,
a first film that is the yttrium-based protective film is formed on the first deposition surface, and
a second film that is an yttrium-based protective film different from the first film is formed on the second deposition surface.
[12] The member according to [11], in which a Vickers hardness HV₂ of the second film is within a range of 40% of y_{A} times a Vickers hardness HV₁ of the first film,
in which when an angle formed between the first deposition surface and the second deposition surface is defined as x_{A} of 0° to 90°, y_{A} is calculated by the following formula (1) when x_{A} is 0° to 60°, and is calculated by the following formula (2) when x_{A} is more than 60°

$${y}_{A} = - 0.000 \; 34751 {x}_{A}^{2} + 0.01538782 {x}_{A} + 1.00625521 \qquad ( 1 )$$

$${y}_{A} = - 0.00197743 {x}_{A} + 0.75229358 . \qquad ( 2 )$$

[13] The member according to [11] or [12], in which a thickness t₂ of the second film is within a range of ±40% of y_{B} times a thickness t₁ of the first film,
in which when an angle formed between the first deposition surface and the second deposition surface is defined as x_{B} of 0° to 170°, y_{B} is calculated by the following formula (3) when x_{B} is 0° to 90°, and is calculated by the following formula (4) when x_{B} is more than 90° and 170° or less:

$${y}_{B} = - 0.000 \; 12389 {x}_{B}^{2} + 0.00659698 {x}_{B} + 0.99721254 \qquad ( 3 )$$

$${y}_{B} = - 0.00005 \; 913 {x}_{B}^{2} + 001099778 {x}_{B} - 0.26784922 . \qquad ( 4 )$$

[14] The member according to any one of [11] to [13], in which a crystallite size S₂ of the second film is within a range of ±40% of y_{C} times a crystallite size S₁ of the first film,
in which when an angle formed between the first deposition surface and the second deposition surface is defined as xc of 0° to 170°, y_{C} is calculated by the following formula (5):

$${y}_{C} = 0.00009 \; 729 {x}_{C}^{2} - 0.00273425 {x}_{C} + 0.99976959 . \qquad ( 5 )$$

[15] The member according to any one of [11] to [14], in which an angle formed between the first deposition surface and the second deposition surface is 100 to 160°.
[16] The member according to any one of [11] to [15],
in which an angle formed between the first deposition surface and the second deposition surface is 90°, and
an HV₁/HV₂ ratio, which is a ratio of a Vickers hardness HV₁ of the first film to a Vickers hardness HV₂ of the second film, is 1.05 to 2.50.
[17] The member according to any one of [11] to [16],
in which an angle formed between the first deposition surface and the second deposition surface is 90°, and
a t₁/t₂ ratio, which is a ratio of a thickness t₁ of the first film to a thickness t₂ of the second film, is 1.5 to 3.5,
in which a unit of the thickness is μm.
[18] The member according to any one of [11] to [17],
in which an angle formed between the first deposition surface and the second deposition surface is 90°, and
a t₁/t₂ ratio, which is a ratio of a thickness t₁ of the first film to a thickness t₂ of the second film, is 2.0 to 6.0,
in which a unit of the thickness is μm.
[19] The member according to any one of [11] to [18],
in which an angle formed between the first deposition surface and the second deposition surface is 90°, and
an S₁/S₂ ratio, which is a ratio of a crystallite size S₁ of the first film to a crystallite size S₂ of the second film, is 0.35 to 0.90,
in which a unit of the crystallite size is nm.
[20] The member according to [19], in which the crystallite size S₁ of the first film is less than 20 nm.
[21] The member according to [19] or [20], in which the crystallite size S₂ of the second film is 15 nm or more.
[22] The member according to any one of [10] to [21], in which a surface roughness of a deposition surface of the substrate is, in terms of an arithmetic average roughness Ra, 0.001 μm to 3.00 μm.
[23] The member according to any one of [10] to [22], in which the substrate has a porosity of 2.0 volume % or less.
[24] The member according to any one of [10] to [23], in which the substrate is made of at least one selected from the group consisting of carbon, ceramic, and metal.
[25] The member according to [24],
in which the ceramic is at least one selected from the group consisting of glass, quartz, aluminum oxide, aluminum nitride, Si-impregnated silicon carbide, and aluminum oxynitride, and
the metal is at least one selected from the group consisting of aluminum and an alloy including aluminum.
[26] The member according to any one of [10] to [25], in which a deposition surface of the substrate has a maximum length of 30 mm or more.
[27] The member according to any one of [10] to [26], including one or more base layers between the substrate and the yttrium-based protective film,
in which the base layer includes at least one oxide selected from the group consisting of Al₂O₃, SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃.
[28] The member according to any one of [10] to [27], which is used in a plasma etching apparatus or a plasma CVD apparatus.
[29]A method for producing the yttrium-based protective film according to any one of [1] to [9], the method including evaporating an evaporation source and depositing the evaporation source onto a substrate while irradiating with ions of at least one element selected from the group consisting of oxygen, argon, neon, krypton, and xenon from an ion gun in a vacuum,
in which Y₂O₃ or a combination of Y₂O₃ and YF₃ is used as the evaporation source.
[30] The method for producing the yttrium-based protective film according to [29], in which at least argon ions are irradiated from the ion gun toward the substrate.

According to the present invention, an yttrium-based protective film having excellent plasma resistance can be provided.

### BRIEF DESCRIPTION OF DRAWINGS

FIG. 1 is a schematic diagram illustrating an example of a member.

FIG. 2 is a schematic diagram illustrating a ring-shaped substrate with a half cut away.

FIG. 3 is a schematic diagram illustrating a part of a cross section of another ring-shaped substrate.

FIG. 4 is a schematic diagram illustrating a part of a cross section of still another ring-shaped substrate.

FIG. 5 is a schematic diagram illustrating an apparatus used for producing an yttrium-based protective film.

FIG. 6 is a schematic diagram illustrating a substrate having a first deposition surface and a second deposition surface.

### DESCRIPTION OF EMBODIMENTS

The terms used in the present invention have the following meanings.

A numerical range represented by using “to” means a range including numerical values described before and after “to” as a lower limit value and an upper limit value.

### [Yttrium-Based Protective Film]

The yttrium-based protective film according to the present embodiment has a porosity of less than 1.5 volume %, a Young's modulus of 100.00 GPa or more, and a Vickers hardness of 8.50 GPa or more, and thus has excellent plasma resistance.

Hereinafter, the yttrium-based protective film according to the present embodiment is described in more detail.

### <Porosity>

For the reason that the yttrium-based protective film has excellent plasma resistance, the porosity of the yttrium-based protective film is less than 1.5 volume %, preferably 1.0 volume % or less, more preferably 0.5 volume % or less, still more preferably 0.3 volume % or less, particularly preferably 0.2 volume % or less, and most preferably 0.1 volume % or less.

In order to adjust the porosity within the above range, it is preferable to produce the yttrium-based protective film by a production method described below.

The porosity of the yttrium-based protective film is determined as follows.

First, using a focused ion beam (FIB), slope processing is performed on a part of the yttrium-based protective film and the substrate described below in a thickness direction at an angle of 52° from the surface of the yttrium-based protective film toward the substrate, thereby exposing a cross section. The exposed cross section is observed at a magnification of 20000 times using a field emission scanning electron microscope (FE-SEM), and a cross-sectional image thereof is captured.

The cross-sectional image is captured at a plurality of locations. Specifically, for example, when the yttrium-based protective film is circular, images are captured at five points in total: one point at a center of the surface of the yttrium-based protective film and four points at positions that are 10 mm inward from the outer periphery, and the size of the cross-sectional image is 6 μm×5 μm. When the thickness of the yttrium-based protective film is 5 μm or more, cross-sectional images are respectively captured at a plurality of imaging locations so that the entire cross section of the yttrium-based protective film can be observed in the thickness direction.

Subsequently, the area of the pore portion in the cross-sectional image is determined by analyzing the obtained cross-sectional image using image analysis software (ImageJ, provided by National Institute of Health). The proportion of the area of the pore portion to the area of the entire cross section of the yttrium-based protective film is calculated and regarded as the porosity (unit: volume %) of the yttrium-based protective film. Regarding pores that are too fine to be detected by the image analysis software (pores with a pore diameter of 20 nm or less), areas thereof are regarded as 0.

### <Young's Modulus>

For the reason that the yttrium-based protective film has excellent plasma resistance, the Young's modulus of the yttrium-based protective film is 100.00 GPa or more, preferably 110.00 GPa or more, more preferably 120.00 GPa or more, and still more preferably 130.00 GPa or more.

On the other hand, the Young's modulus of the yttrium-based protective film is, for example, 250.00 GPa or less, and preferably 200.00 GPa or less.

The Young's modulus of the yttrium-based protective film is measured at 20° C. by a dynamic elastic modulus test method (ultrasonic pulse method) described in Japanese Industrial Standards (JIS R1602: 1995).

### <Vickers Hardness>

For the reason that the yttrium-based protective film has excellent plasma resistance, the Vickers hardness of the yttrium-based protective film is 8.50 GPa or more, preferably 9.50 GPa or more, more preferably 10.50 GPa or more, still more preferably 11.50 GPa or more, and particularly preferably 12.50 GPa or more.

On the other hand, the Vickers hardness of the yttrium-based protective film is, for example, 20.00 GPa or less, and preferably 18.00 GPa or less.

In order to adjust the Vickers hardness within the above range, it is preferable to produce the yttrium-based protective film by the production method described below.

The Vickers hardness of the yttrium-based protective film is measured using a nanoindentation tester (iMicro, manufactured by KLA). More specifically, the nanoindentation hardness (unit: GPa) is measured by changing the load within 0 mN to 50 mN. The measurement is performed at 20 locations, and the average value is regarded as the Vickers hardness.

Other test conditions are as follows.

As a nanoindentation tester, “iMicro” manufactured by KLA is used, and a sample (yttrium-based protective film disposed on the surface of the substrate) is fixed to a sample stage.

A thermoplastic temporary adhesive “crystal bond 555” (fluidization temperature: 48° C.) manufactured by Aremco is used for fixing the sample.

As an actuator, “inForce50” that can be used with a load up to 50 mN is selected.

As an indenter, a Berkovich indenter (tip curvature radius: 20 nm) having a triangular pyramidal tip is used.

### <Young's Modulus/Vickers Hardness>

In the yttrium-based protective film according to the present embodiment, a ratio (Young's modulus/Vickers hardness) of the Young's modulus (unit: GPa) to the Vickers hardness (unit: GPa) is preferably 16.5 or less, more preferably 15.5 or less, still more preferably 14.5 or less, and particularly preferably 13.5 or less for the reason that the yttrium-based protective film has excellent plasma resistance.

On the other hand, the ratio (Young's modulus/Vickers hardness) is preferably 8.0 or more, and more preferably 9.0 or more for the reason that the yttrium-based protective film does not become brittle.

### <Ar Content>

In the present embodiment, the yttrium-based protective film contains a certain amount of argon (Ar). Accordingly, the Vickers hardness of the yttrium-based protective film is increased.

First, in the present embodiment, the yttrium-based protective film is formed by an ion-assisted deposition (TAD) method. The IAD method is generally a method in which an evaporation source is evaporated and deposited onto a substrate while irradiating with ions in vacuum.

In this case, for example, irradiating with argon (Ar), which has a high kinetic energy, together with oxygen (O) ions increases the strength with which the evaporated evaporation source is injected into the substrate, as compared with the irradiation with only oxygen (O) ions.

Accordingly, it is presumed that the yttrium-based protective film containing Ar is formed and the formed yttrium-based protective film has a large Vickers hardness.

Specifically, for the reason that the Vickers hardness of the yttrium-based protective film is increased, the content of argon (Ar content) in the yttrium-based protective film is preferably 0.10 atom % or more, more preferably 0.15 atom % or more, and still more preferably 0.20 atom % or more.

However, when the Ar content in the yttrium-based protective film is too large, the Vickers hardness of the yttrium-based protective film tends to decrease.

Therefore, the Ar content in the yttrium-based protective film is preferably 3.00 atom % or less, more preferably 2.00 atom % or less, still more preferably 1.50 atom % or less, particularly preferably 1.00 atom % or less, and most preferably 0.50 atom % or less.

That is, the Ar content in the yttrium-based protective film is preferably 0.10 atom % to 3.00 atom %.

The method for measuring the Ar content in the yttrium-based protective film is described below.

### <Composition>

In the present embodiment, the yttrium content in the yttrium-based protective film is preferably 5 atom % or more, more preferably 10 atom % or more, and still more preferably 20 atom % or more for the reason that the yttrium-based protective film has excellent plasma resistance. From the viewpoint of enhancing the electrical insulation, the yttrium content in the yttrium-based protective film is preferably 70 atom % or less, more preferably 60 atom % or less, and still more preferably 50 atom % or less.

In the present embodiment, the yttrium-based protective film preferably contains, for example, yttrium oxides or yttrium oxyfluorides.

Hereinafter, each of the cases where the yttrium-based protective film contains yttrium oxides or yttrium oxyfluorides is described.

### <<Yttrium Oxides>>

First, a case where the yttrium-based protective film contains yttrium oxide (Y₂O₃) is described.

In this case, the Y₂O₃ content in the yttrium-based protective film is preferably 95 mass % or more, and more preferably 98 mass % or more.

The Y₂O₃ content in the yttrium-based protective film produced using only Y₂O₃ as the evaporation source by the production method described below satisfies the above range.

### (Degree of Orientation)

When increasing the area of the yttrium-based protective film, from the viewpoint of preventing the occurrence of cracks (including wrinkles; the same applies below) in the yttrium-based protective film, a higher degree of orientation of the (222) plane of Y₂O₃ in the yttrium-based protective film (hereinafter, also simply referred to as “degree of orientation”) is preferable.

Therefore, the degree of orientation of the yttrium-based protective film is preferably 50% or more, more preferably 65% or more, still more preferably 80% or more, yet still more preferably 85% or more, particularly preferably 90% or more, more particularly preferably 95% or more, even more preferably 98% or more, and most preferably 99% or more.

In order to adjust the degree of orientation within the above range, it is preferable to produce the yttrium-based protective film by the production method described below.

The degree of orientation is the proportion (unit: %) of a peak intensity of the (222) plane when the total of the peak intensities of the respective surfaces of Y₂O₃ in the XRD pattern of the yttrium-based protective film is 100.

The XRD pattern of the yttrium-based protective film (and the base layer described below) is obtained by performing an XRD measurement in a micro portion 2D (two-dimensional) mode using an X-ray diffractometer (D8 DISCOVER Plus, manufactured by Bruker) under the following conditions.
X-ray source: CuKα ray (output: 45 kV, current: 120 mA)
Scanning range: 2θ=10° to 80°
Step time: 0.2 s/step
Scan speed: 10°/min
Step width: 0.02°
Detector: multi-mode detector EIGER (2D mode)
Incident side optical system: multilayer mirror+1.0 mmφ micro slit+1.0 mmφ collimator
Light receiving side optical system: OPEN

### (Yttrium Oxyfluoride)

Next, a case where the yttrium-based protective film contains yttrium oxyfluorides is described.

Examples of the chemical formula representing yttrium oxyfluorides include YOF and Y₅O₄F₇. YOF is an oblique crystal having a low hardness, whereas Y₅O₄F₇ has a special crystal structure called a rhombohedron and has a high hardness.

In the present embodiment, the yttrium-based protective film preferably has a high proportion of Y₅O₄F₇ having a rhombohedral crystal structure. That is, it is preferable that a peak intensity ratio of Y₅O₄F₇ in the X-ray diffraction pattern is at least a certain value. Accordingly, the yttrium-based protective film is hard and exhibits a Vickers hardness at least a certain value.

### (Peak Intensity Ratio)

The peak intensity ratio of Y₅O₄F₇ in the X-ray diffraction pattern of the yttrium-based protective film (hereinafter, also referred to as “Y₅O₄F₇ peak intensity ratio” or simply “peak intensity ratio”) is 60% or more, preferably 80% or more, more preferably 90% or more, and still more preferably 95% or more.

In order to adjust the Y₅O₄F₇ peak intensity ratio within the above range, it is preferable to produce the yttrium-based protective film by the production method described below.

The Y₅O₄F₇ peak intensity ratio is a proportion (unit: %) of the main peak intensity of Y₅O₄F₇ when the total of the main peak intensities of crystal phases shown below is 100 in the X-ray diffraction (XRD) pattern of the yttrium-based protective film.

As for the main peak of each crystal phase, the main peak of Y₅O₄F₇ appears in the vicinity of 2θ=28.1°, the main peak of Y₂O₃ appears in the vicinity of 2θ=29.2°, and the main peak of YOF appears in the vicinity of 2θ=29.2°.

At the main peak position of Y₅O₄F₇, the peak of Y₆O₅F₈ crystal and the peak of Y₇O₆F₉ crystal overlap. Furthermore, the main peak of YF₃ also overlaps the main peak position of Y₅O₄F₇.

The peaks at the main peak position of Y₅O₄F₇ are all treated as peaks of Y₅O₄F₇.

When the YF₃ crystal is present, the peak intensity in the vicinity of 2θ=24.5°, which is the second main peak of the YF₃ crystal, is multiplied by 1.3 and converted to an equivalent main peak intensity, and this peak intensity is defined as the main peak intensity of YF₃. At this time, the intensity of the second main peak of the YF₃ crystal converted by being multiplied by 1.3 is subtracted from the intensity of the peak of Y₅O₄F₇ (peaks located at the main peak position of Y₅O₄F₇). If the intensity (relative intensity) of the second main peak of the YF₃ crystal is “2.0” and the intensity (relative intensity) of the peak at the main peak position of Y₅O₄F₇ is “6.0”, the intensity of the second main peak of the YF₃ crystal is converted into “2.6” (=2.0×1.3). Therefore, the intensity of the peak at the main peak position of Y₅O₄F₇ is reduced by the converted intensity of the second main peak of the YF₃ crystal to obtain “3.4” (=6.0−2.6).

The XRD pattern of the yttrium-based protective film is obtained by performing an XRD measurement in a micro portion 2D (two-dimensional) mode using an X-ray diffractometer (D8 DISCOVER Plus, manufactured by Bruker) under the above-described conditions.

### (Content of Each Element)

The yttrium-based protective film contains yttrium (Y), oxygen (O), and fluorine (F) when the yttrium-based protective film contains yttrium oxyfluorides.

Here, the Y content in the yttrium-based protective film is preferably 20 atom % or more, more preferably 25 atom % or more, still more preferably 26 atom % or more, particularly preferably 27 atom % or more, and most preferably 27.5 atom % or more.

On the other hand, the Y content in the yttrium-based protective film is preferably 35 atom % or less, more preferably 30 atom % or less, still more preferably 29 atom % or less, and particularly preferably 28 atom % or less.

The O content in the yttrium-based protective film is preferably 20 atom % or more, more preferably 21 atom % or more, still more preferably 22 atom % or more, particularly preferably 23 atom % or more, and most preferably 24 atom % or more.

On the other hand, the O content in the yttrium-based protective film is preferably 35 atom % or less, more preferably 30 atom % or less, still more preferably 28 atom % or less, particularly preferably 26 atom % or less, and most preferably 25 atom % or less.

The F content in the yttrium-based protective film is, for example, 25 atom % or more, preferably 35 atom % or more, more preferably 40 atom % or more, still more preferably 44 atom % or more, particularly preferably 47 atom % or more, and most preferably 48 atom % or more.

On the other hand, the F content in the yttrium-based protective film is, for example, 65 atom % or less, preferably 60 atom % or less, more preferably 55 atom % or less, still more preferably 52 atom % or less, yet still more preferably 50 atom % or less, particularly preferably 49.5 atom % or less, and most preferably 49 atom % or less.

In order to adjust the content of each element within the above range, for example, in the production method described below, production conditions such as the amount of the evaporation source are appropriately adjusted.

The content (unit: atom %) of each element in the yttrium-based protective film is measured using an energy dispersive X-ray spectrometer (EX-250SE, manufactured by Horiba, Ltd.).

### (F/O Ratio)

The F/O ratio, which is a ratio of the F content (unit: atom %) to the O content (unit: atom %) in the yttrium-based protective film, is preferably less than 2.80, more preferably less than 2.50, and still more preferably less than 2.15.

On the other hand, the F/O ratio of the yttrium-based protective film is preferably more than 1.50, more preferably more than 1.70, and still more preferably more than 1.90.

### (Degree of Orientation: Full Width at Half Maximum of Rocking Curve)

From the viewpoint of preventing the occurrence of cracks in the yttrium-based protective film, a higher degree of orientation of the (151) plane of Y₅O₄F₇ in the yttrium-based protective film (hereinafter, also simply referred to as “degree of orientation”) is preferable.

As an index of the degree of orientation, the full width at half maximum of a rocking curve of the (151) plane of Y₅O₄F₇ is used. Specifically, the rocking curve of a peak of the (151) plane of Y₅O₄F₇, which is obtained by using a two-dimensional detector, is integrated in a 2θ direction, and the orientation is evaluated using its full width at half maximum. The smaller the full width at half maximum (unit: °) is, the higher the degree of orientation is.

The full width at half maximum of the rocking curve of the (151) plane of Y₅O₄F₇ is preferably 40° or less, more preferably 300 or less, still more preferably 250 or less, yet still more preferably 200 or less, particularly preferably 150 or less, and most preferably 10° or less.

In order to adjust the degree of orientation within the above range, it is preferable to produce the yttrium-based protective film by the production method described below.

### <Crystallite Size>

As described above, for example, the particles detached from the member exposed to the plasma may adhere to a semiconductor substrate and become foreign matter causing circuit defects.

At this time, as the sizes of the particles are reduced, the occurrence of defects can be prevented.

Therefore, the crystallite size of the yttrium-based protective film is preferably 30 nm or less, more preferably 20 nm or less, and still more preferably 15 nm or less.

On the other hand, as the crystallite size of the yttrium-based protective film increases, the change in the crystallite size when heated is small and stable, and the heat resistance is improved.

Therefore, the crystallite size of the yttrium-based protective film is preferably 5 nm or more, more preferably 7 nm or more, and still more preferably 10 nm or more.

Therefore, the crystallite size of the yttrium-based protective film is preferably 5 nm to 30 nm.

In order to adjust the crystallite size within the above range, it is preferable to produce the yttrium-based protective film by the production method described below.

The crystallite size of the yttrium-based protective film is determined using Scherrer's formula based on data of XRD pattern obtained by the XRD measurement of the mirror-polished yttrium-based protective film.

### <Thickness>

The thickness of the yttrium-based protective film is preferably 0.01 μm or more, more preferably 0.1 μm or more, still more preferably 0.5 μm or more, particularly preferably 1.0 μm or more, and most preferably 2.0 μm or more.

On the other hand, the thickness of the yttrium-based protective film is preferably 30.0 μm or less, more preferably 25.0 μm or less, still more preferably 20.0 μm or less, particularly preferably 15.0 μm or less, and most preferably 10.0 μm or less.

Therefore, the thickness of the yttrium-based protective film is preferably 0.01 μm to 30.0 μm.

The thickness of the yttrium-based protective film is measured as follows.

The cross section of the yttrium-based protective film is observed using a scanning electron microscope (SEM), the thickness of the yttrium-based protective film is measured at any five points, and an average value of the thickness of the measured five points is regarded as the thickness (unit: μm) of the yttrium-based protective film.

### <Compressive Stress>

The stress (internal stress, residual stress) of the yttrium-based protective film is preferably not a tensile stress but a compressive stress.

The compressive stress of the yttrium-based protective film is preferably 100 MPa or more, more preferably 300 MPa or more, still more preferably 500 MPa or more, and particularly preferably 700 MPa or more.

On the other hand, the compressive stress of the yttrium-based protective film is preferably 1700 MPa or less, more preferably 1600 MPa or less, and still more preferably 1500 MPa or less.

The compressive stress of the yttrium-based protective film is determined as follows.

An yttrium-based protective film is formed on a quartz glass substrate, a surface shape of the formed yttrium-based protective film is measured using a surface shape measurement apparatus (SURFCOM NEX 241 SD2-13, manufactured by Tokyo Seimitsu Co., Ltd.), and the compressive stress (film stress a) of the yttrium-based protective film is determined based on the Stoney's equation (the following equation).

$$σ = {Yd}^{2} / ( 6 c ( 1 - v ) t )$$

In the above equation, σ: film stress, Y: Young's modulus of substrate, d: thickness of substrate, v: Poisson's ratio of substrate, t: thickness of yttrium-based protective film, and c: radius of curvature.

### [Member]

Next, the member is described.

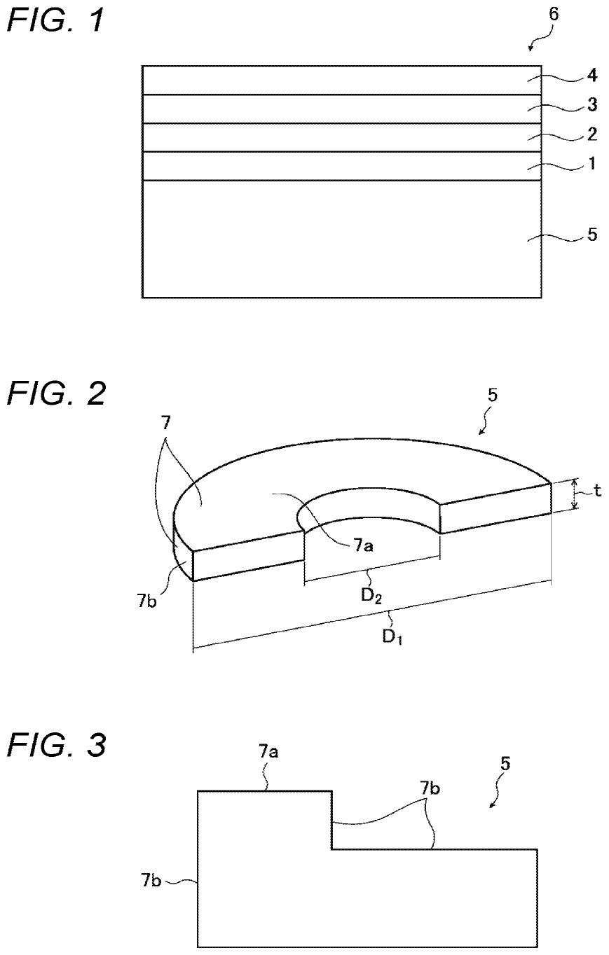

First, the member is schematically described with reference to FIG. 1.

FIG. 1 is a schematic diagram illustrating an example of the member 6.

The member 6 includes at least a substrate 5 and an yttrium-based protective film 4 in this order.

For example, the yttrium-based protective film according to the present embodiment described above is used as the yttrium-based protective film 4.

As illustrated in FIG. 1, a base layer (a base layer 1, a base layer 2, and a base layer 3) may be disposed between the substrate 5 and the yttrium-based protective film 4.

However, the number of the base layers is not limited to three.

Hereinafter, each part of the member is described in detail.

### <Substrate>

The substrate has at least a surface on which an yttrium-based protective film (or a base layer) is formed. Hereinafter, this surface may be referred to as a “deposition surface” for convenience.

### <<Material>>

The material of the substrate is appropriately selected depending on the use of the member or the like.

The substrate is formed of, for example, at least one selected from the group consisting of carbon (C), ceramic, and metal.

Here, the ceramic is, for example, at least one selected from the group consisting of glass (soda lime glass or the like), quartz, aluminum oxide (Al₂O₃), aluminum nitride (AlN), Si-impregnated silicon carbide, and aluminum oxynitride (AlON).

The Si-impregnated silicon carbide is obtained by heating and melting elemental Si and impregnating silicon carbide (SiC) with the molten Si.

The metal is, for example, at least one selected from the group consisting of aluminum (Al) and an alloy containing aluminum (Al). The metal is preferably Al.

### <<Shape>>

The shape of the substrate is not particularly limited, and examples thereof include a flat plate shape, a ring shape, a dome shape, a protruding shape, and a recessed shape. The shape of the substrate is appropriately selected depending on the use of the member.

### <<Surface Roughness of Deposition Surface>>

The surface roughness of the deposition surface of the substrate, in terms of the arithmetic average roughness Ra, is preferably 3.00 μm or less, more preferably 2.50 μm or less, still more preferably 1.50 μm or less, yet still more preferably 1.00 μm or less, particularly preferably 0.60 μm or less, more particularly preferably 0.40 μm or less, even more preferably 0.20 μm or less, and most preferably 0.08 m or less.

On the other hand, the surface roughness of the deposition surface of the substrate is preferably 0.001 μm or more, and more preferably 0.01 μm or more as the arithmetic average roughness Ra.

The surface roughness (arithmetic average roughness Ra) of the deposition surface is measured in accordance with JIS B 0601: 2001.

### <<Maximum Length of Deposition Surface>>

The maximum length of the deposition surface of the substrate is preferably 30 mm or more, more preferably 70 mm or more, still more preferably 100 mm or more, and particularly preferably 150 mm or more.

The term “maximum length” means the maximum length that the deposition surface has. Specifically, for example, when the deposition surface is circular in plan view, the maximum length is the diameter of the circle. When the deposition surface is a ring in plan view, the maximum length is the outer diameter thereof. When the deposition surface is a rectangle in plan view, the maximum length is the length of the maximum diagonal line.

On the other hand, the maximum length of the deposition surface is, for example, 2000 mm or less, preferably 1500 mm or less, more preferably 1000 mm or less, still more preferably 700 mm or less, and most preferably 500 mm or less.

FIG. 2 is a schematic diagram illustrating a ring-shaped substrate 5 with a half cut away.

For example, when the substrate 5 shown in FIG. 2 has an outer diameter D₁ of 100 mm, an inner diameter D₂ of 90 mm, and a thickness t of 5 mm, the maximum length of the substrate 5 is 100 mm.

The substrate 5 has a deposition surface 7, and as illustrated in FIG. 2, the deposition surface 7 may have a first deposition surface 7a and a second deposition surface 7b different from the first deposition surface 7a. The first deposition surface 7a defines, for example, the maximum length (outer diameter D₁) of the deposition surface 7.

The proportion of the area of the second deposition surface 7b to the total area of the deposition surface 7 is, for example, 60% or less.

FIG. 3 is a schematic diagram illustrating a part of a cross section of another ring-shaped substrate 5.

As shown in FIG. 3, the substrate 5 may have a plurality of second deposition surfaces 7b.

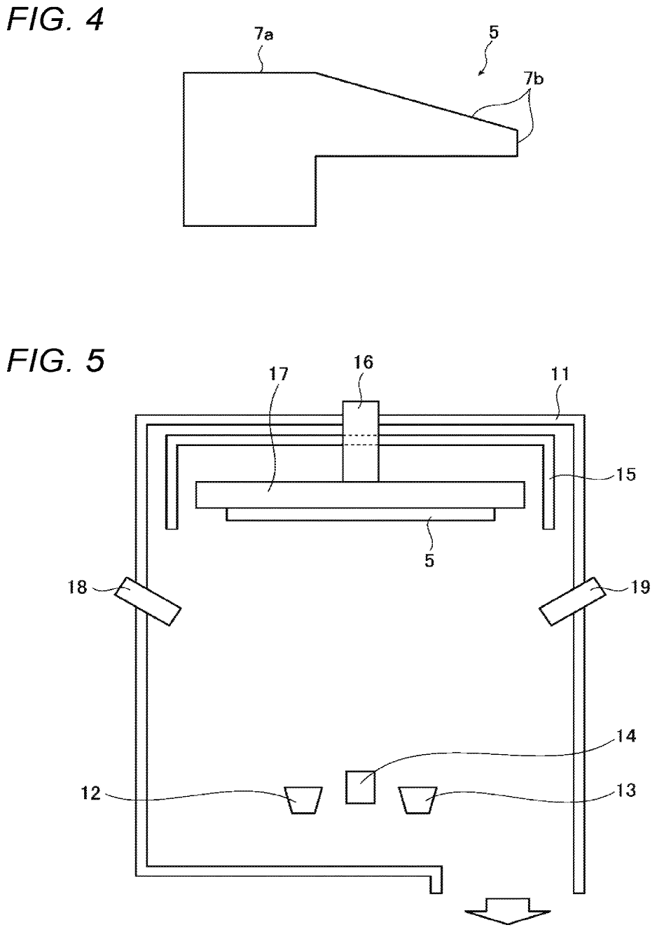

FIG. 4 is a schematic diagram illustrating a part of a cross section of still another ring-shaped substrate 5.

### <Base Layer>

As described above, one or more base layers may be disposed between the substrate and the yttrium-based protective film.

By forming the base layer, the tensile stress of the yttrium-based protective film is relaxed to generate the compressive stress, or the adhesion of the yttrium-based protective film to the substrate is increased.

### <<Number of Layers>>

The upper limit of the number of the base layers is not particularly limited, and the number of the base layers is preferably 5 or less, more preferably 4 or less, still more preferably 3 or less, particularly preferably 2 or less, and most preferably 1.

### <<State of Layer>>

The base layer is preferably an amorphous layer or a microcrystalline layer (amorphous layer containing crystals).

### <<Composition>>

The base layer preferably contains at least one oxide selected from the group consisting of Al₂O₃, SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃.

When two or more base layers are disposed between the substrate and the yttrium-based protective film, the oxides in the base layers are preferably different from each other between the adjacent base layers.

Specific examples of the case where the oxides in the adjacent base layers are different from each other include a case where the oxide in the base layer 1 is “SiO₂”, the oxide in the base layer 2 is “Al₂O₃+SiO₂”, and the oxide in the base layer 3 is “Al₂O₃”.

### <<Thickness>>

The thickness of the base layer is preferably 0.05 μm or more, more preferably 0.1 μm or more, still more preferably 0.2 m or more, yet still more preferably 0.5 μm or more, particularly preferably 0.8 μm or more, and most preferably 1.1 μm or more.

On the other hand, the thickness of the base layer is, for example, 15.0 μm or less, preferably 10.0 μm or less, more preferably 7.0 μm or less, particularly preferably 5.0 μm or less, and most preferably 3.0 m or less.

The thickness of the base layer is measured in the same manner as the thickness of the yttrium-based protective film.

### <Use of Member>

The member according to the present embodiment is used as, for example, a member such as a top plate in a semiconductor device producing apparatus (a plasma etching apparatus, a plasma CVD apparatus, or the like).

However, the application is not limited thereto.

### [Method for Producing Yttrium-Based Protective Film and Member]

Next, the method of producing the yttrium-based protective film according to the present embodiment is described.

The following description also describes a method of producing the member according to the present embodiment.

In the present embodiment, the ion-assisted deposition (LAD) method is used.

Schematically, an evaporation source (Y₂O₃, YF₃, etc.) is evaporated and deposited onto the substrate while irradiating with ions in a vacuum, thereby forming the yttrium-based protective film.

The yttrium-based protective film can be formed very densely by using the IAD method. That is, the obtained yttrium-based protective film has a low porosity.

In contrast, a large number of pores are likely to remain in the yttrium-based protective film, which is obtained by a method such as a thermal spraying method, an aerosol deposition (AD) method, or an ion plating (IP) method.

### <Apparatus Configuration>

FIG. 5 is a schematic diagram illustrating an apparatus used for producing the yttrium-based protective film.

The apparatus shown in FIG. 5 includes a chamber 11. The inside of the chamber 11 can be evacuated to a vacuum by operating a vacuum pump (not illustrated).

Crucibles 12 and 13, and an ion gun 14 are disposed inside the chamber 11, and a holder 17 is disposed above them.

The holder 17 is integrated with a supporting shaft 16 and rotates with the rotation of the supporting shaft 16. A heater 15 is disposed around the holder 17.

The above-described substrate 5 is held by the holder 17 in a state where the deposition surface of the substrate 5 faces downward. The substrate 5 held by the holder 17 rotates with the rotation of the holder 17 while being heated by the heater 15.

Further, quartz crystal film thickness monitors 18 and 19 are attached to the chamber 11.

### <Formation of Yttrium-Based Protective Film (Part 1)>

A case where the yttrium-based protective film (not shown in FIG. 5) containing yttrium oxide (Y₂O₃) is formed on the substrate 5 in the apparatus shown in FIG. 5 is described.

First, the evaporation source Y₂O₃ is charged into one or both of the crucibles 12 and 13.

After the substrate 5 is held by the holder 17, the inside of the chamber 11 is evacuated to make a vacuum state.

Next, the holder 17 is rotated while driving the heater 15. Accordingly, the substrate 5 is rotated while being heated.

In this state, ion assisted deposition is performed to form a film on the substrate 5.

That is, the evaporation source Y₂O₃ charged in one or both of the crucibles 12 and 13 is evaporated while irradiating with ions (ion beams) from the ion gun 14.

The evaporation source melts and evaporates by being irradiated with electron beams (not illustrated).

In this way, the evaporated evaporation source adheres to the deposition surface of the substrate 5 (or a surface of the base layer when the base layer is present), and an yttrium-based protective film containing yttrium oxide (Y₂O₃) is formed.

The ions irradiated from the ion gun 14 are preferably ions of at least one element selected from the group consisting of oxygen, argon, neon, krypton, and xenon, and more preferably argon ions.

As the ions irradiated from the ion gun 14, ions of at least two elements selected from the group consisting of oxygen, argon, neon, krypton, and xenon are more preferably used, and ions of oxygen and argon are more preferably used in combination.

Accordingly, it is presumed that a certain amount of argon (Ar) is included in the yttrium-based protective film to be formed.

### <<Internal Pressure of Chamber>>

The deposition is performed in vacuum. Specifically, for the reason that the porosity of the yttrium-based protective film to be formed is reduced, the internal pressure of the chamber 11 is preferably 6×10⁻² Pa or less, more preferably 5×10⁻² Pa or less, and still more preferably 3×10⁻² Pa or less.

On the other hand, the internal pressure of the chamber 11 is preferably more than 1×10⁻⁶ Pa, more preferably 1×10⁻⁵ Pa or more, and still more preferably 1×10⁻⁴ Pa or more.

### <<Temperature of Substrate>>

During the deposition, the temperature of the substrate 5 heated by the heater 15 is preferably 200° C. or higher, more preferably 270° C. or higher, still more preferably 320° C. or higher, particularly preferably 370° C. or higher, and most preferably 400° C. or higher.

On the other hand, the temperature is preferably 600° C. or lower, more preferably 500° C. or lower, and still more preferably 450° C. or lower.

### <<Deposition Rate>>

The rates (deposition rate) at which films are formed by evaporating the evaporation sources in the crucibles 12 and 13 are respectively monitored in advance using the quartz crystal film thickness monitors 18 and 19.

The deposition rate is adjusted by controlling conditions of the electron beam irradiated to the evaporation source and conditions (current value, current density, etc.) of the ion beam of the ion gun 14.

During the formation of the yttrium-based protective film, the deposition rate (unit: nm/min) of each evaporation source is adjusted to a desired value.

The deposition rate of the evaporation source Y₂O₃ is preferably 1 nm/min or more, more preferably 1.5 nm/min or more, and still more preferably 2 nm/min or more.

The deposition rate of the evaporation source Y₂O₃ is preferably 20 nm/min or less, more preferably 15 nm/min or less, still more preferably 10 nm/min or less, yet still more preferably 5 nm/min or less, particularly preferably 3.5 nm/min or less, and most preferably 2.1 nm/min or less.

### <<Conditions of Ion Irradiation>>

The distance between the ion gun 14 and the substrate 5 is preferably 700 mm or more, and more preferably 900 mm or more. On the other hand, the distance is preferably 1500 mm or less, and more preferably 1300 mm or less.

The ion beam current value is preferably 1000 mA or more, and more preferably 1500 mA or more. On the other hand, the ion beam current value is preferably 3000 mA or less, and more preferably 2500 mA or less.

The ion beam current density is preferably 40 μA/cm² or more, more preferably 65 μA/cm² or more, still more preferably 75 μA/cm² or more, and particularly preferably 77 μA/cm² or more. On the other hand, the ion beam current density is preferably 140 μA/cm² or less, more preferably 120 μA/cm² or less, and still more preferably 100 μA/cm² or less.

### <<Ar/O Ratio>>

As described above, it is preferable to use argon ions and oxygen ions in combination as the ions irradiated from the ion gun 14.

At this time, the Ar/O ratio, which is a ratio of an amount of argon (Ar) ions to an amount of oxygen (O) ions, is preferably more than 2/50, more preferably 4/50 or more, still more preferably more than 4/50, yet still more preferably 5/50 or more, particularly preferably 6/50 or more, more particularly preferably 7/50 or more, even still more preferably 8/50 or more, and most preferably 10/50 or more.

On the other hand, the Ar/O ratio is 25/50 or less, preferably 20/50 or less, more preferably 15/50 or less, and still more preferably 12/50 or less.

The Ar/O ratio is a ratio of an amount (unit: W/m²) of argon (Ar) ions irradiated from the ion gun 14 toward the substrate 5 to an amount (unit: W/m²) of oxygen (O) ions similarly irradiated from the ion gun 14 toward the substrate 5.

Here, “W/m²” is a unit indicating kinetic energy (ion energy flux) crossing a unit area per unit time.

### <Formation of Yttrium-Based Protective Film (Part 2)>

Next, a case where the yttrium-based protective film (not shown in FIG. 5) containing yttrium oxyfluoride is formed on the substrate 5 is described.

First, the evaporation source Y₂O₃ is charged in one crucible 12, and the evaporation source YF₃ is charged in the other crucible 13.

After the substrate 5 is held by the holder 17, the inside of the chamber 11 is evacuated to make a vacuum state.

Next, the holder 17 is rotated while driving the heater 15. Accordingly, the substrate 5 is rotated while being heated.

In this state, ion assisted deposition is performed to form a film on the substrate 5.

That is, the evaporation source Y₂O₃ in the crucible 12 and the evaporation source YF₃ in the crucible 13 are evaporated in parallel while irradiating with ions (ion beams) from the ion gun 14.

The evaporation source melts and evaporates by being irradiated with electron beams (not illustrated).

In this way, the evaporated evaporation source adheres to the deposition surface of the substrate 5 (or the surface of the base layer when the base layer is present), and an yttrium-based protective film containing yttrium oxyfluoride is formed.

The ions irradiated from the ion gun 14 conform to the case where the yttrium-based protective film containing yttrium oxide (Y₂O₃) is formed.

### <<Deposition Rate>>

The ratio of deposition rate (Y₂O₃/YF₃) of the deposition rate (unit: nm/min) of the evaporation source Y₂O₃ to the deposition rate (unit: nm/min) of the evaporation source YF₃ is preferably 1/9.5 or more, more preferably 1/8.0 or more, still more preferably 1/6.0 or more, and particularly preferably 1/4.5 or more.

On the other hand, the ratio of deposition rate s(Y₂O₃/YF₃) is preferably 1/1.1 or less, more preferably 1/1.3 or less, still more preferably 1/1.8 or less, and particularly preferably 1/2.5 or less.

The total rate of the deposition rate of the evaporation source Y₂O₃ and the deposition rate of the evaporation source YF₃ is preferably 5 nm/min or more, more preferably 8 nm/min or more, and still more preferably 10 nm/min or more. On the other hand, the total rate is preferably 50 nm/min or less, more preferably 35 nm/min or less, and still more preferably 20 nm/min or less.

### <<Internals Pressure of Chamber, Temperature of Substrate, Conditions of Ion Irradiation, and Ar/O Ratio>>

The internal pressure of the chamber, the temperature of the substrate, the conditions of ion irradiation, and the Ar/O ratio when forming the yttrium-based protective film containing yttrium oxyfluoride conform to the case where the yttrium-based protective film containing yttrium oxide (Y₂O₃) is formed.

### <Formation of Base Layer>

Before the yttrium-based protective film is formed, the above-described base layer (for example, the base layer 1, the base layer 2, and the base layer 3) is preferably formed on the deposition surface of the substrate 5.

Similarly to the yttrium-based protective film, the base layer is formed by ion assisted deposition.

For example, when a base layer made of Al₂O₃ is formed, Al₂O₃ is charged in one or both of the crucible 12 and the crucible 13 as an evaporation source, and the evaporation source is evaporated while irradiating with ions (ion beams) from the ion gun 14 to adhere the evaporation source to the deposition surface of the substrate 5.

Conditions for forming the base layer conform to the conditions for forming the yttrium-based protective film.

The substrate may contain water of crystallization.

For example, when the temperature of a substrate made of aluminum oxide (Al₂O₃) is increased from room temperature, the generation of water of crystallization due to a hydrate which is a low-temperature stable phase of aluminum oxide (for example, boehmite y alumina) is observed at a temperature around 520° C.

When moisture caused by the water of crystallization of the substrate is contained in the formed yttrium-based protective film, the number of hydrogen atoms in the yttrium-based protective film tends to increase.

Therefore, before the evaporation source Y₂O₃ adheres to the deposition surface of the substrate (that is, before the yttrium-based protective film is formed), the base layer is formed on the deposition surface of the substrate.

Accordingly, at least the deposition surface of the substrate is covered, and therefore, water of crystallization of the substrate is less likely to be contained in the formed yttrium-based protective film, and further, the number of hydrogen atoms in the yttrium-based protective film is reduced, which is preferable.

### <Pre-Heating of Substrate>

For the reason that water of crystallization of the substrate is less likely to be contained in the yttrium-based protective film, it is preferable to heat (preheat) the substrate at a high temperature before forming the yttrium-based protective film.

The preheating temperature is preferably 300° C. or higher, more preferably 400° C. or higher, still more preferably 450° C. or higher, and particularly preferably 500° C. or higher.

On the other hand, the preheating temperature is, for example, 800° C. or lower, preferably 750° C. or lower, and more preferably 700° C. or lower.

The preheating time is preferably 60 minutes or longer, more preferably 120 minutes or longer, still more preferably 240 minutes or longer, and particularly preferably 480 minutes or longer.

On the other hand, the preheating time is preferably 1200 minutes or shorter, more preferably 1000 minutes or shorter, still more preferably 800 minutes or shorter, and particularly preferably 600 minutes or shorter.

The preheating atmosphere is, for example, an air atmosphere.

### <Angle Dependency>

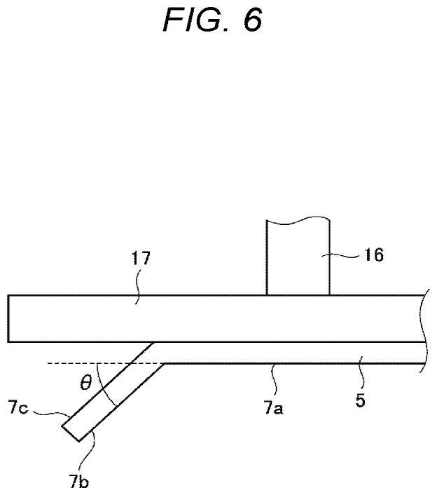

FIG. 6 is a schematic diagram illustrating the substrate 5 having the first deposition surface 7a and the second deposition surface 7b.

The substrate 5 illustrated in FIG. 6 is held by the holder 17 in the chamber 11 (not illustrated in FIG. 6) with the first deposition surface 7a facing downward. Other configurations are the same as those of the apparatus described based on FIG. 5, and thus the description thereof is omitted.

The angle θ formed between the first deposition surface 7a and the second deposition surface 7b is, for example, 0° or more, and preferably 10° or more. On the other hand, the angle θ is, for example, 180° or less, preferably 170° or less, and more preferably 1600 or less. The angle θ may be 90°.

With the above-described production method, the yttrium-based protective film is formed on the deposition surfaces (the first deposition surface and the second deposition surface) of the substrate.

The yttrium-based protective film formed on the first deposition surface is referred to as a “first film”, and the yttrium-based protective film formed on the second deposition surface is referred to as a “second film”.

The first film is, for example, the yttrium-based protective film of the present embodiment described above.

The second film is, for example, an yttrium-based protective film different from the first film.

The substrate has at least a first deposition surface and a second deposition surface as deposition surfaces, and may further have another deposition surface.

### <<Vickers Hardness of Yttrium-Based Protective Film>>

The Vickers hardness HV₂ of the second film is preferably within a range of ±40% of y_{A} times the Vickers hardness HV₁ of the first film, more preferably within a range of ±30% thereof, and still more preferably within a range of ±20% thereof.

Here, when the angle θ formed between the first deposition surface and the second deposition surface is defined as x_{A} of 0° to 90°, y_{A} is calculated by the following formula (1) when x_{A} is 0° to 60°, and is calculated by the following formula (2) when x_{A} is more than 60°

$${y}_{A} = - 0.00034 \; 751 {x}_{A}^{2} + 0.01538782 {x}_{A} + 1.00625521 \qquad ( 1 )$$

$${y}_{A} = - 0.00197743 {x}_{A} + 0.75229358 \qquad ( 2 )$$

When the angle θ formed between the first deposition surface and the second deposition surface is 90°, the HV₁/HV₂ ratio, which is a ratio of the Vickers hardness HV₁ of the first film to the Vickers hardness HV₂ of the second film, is preferably 1.05 or more, more preferably 1.20 or more, and still more preferably 1.35 or more. On the other hand, in this case, the HV₁/HV₂ ratio is preferably 2.50 or less, more preferably 2.30 or less, and still more preferably 2.10 or less.

### <<Thickness of Yttrium-Based Protective Film>>

The thickness t₂ of the second film is preferably within a range of 40% of y_{B} times the thickness t₁ of the first film, more preferably within a range of 30% thereof, and still more preferably within a range of 20% thereof.

Here, when the angle θ formed between the first deposition surface and the second deposition surface is defined as x_{B} of 0° to 170°, y_{B} is calculated by the following formula (3) when x_{B} is 0° to 90°, and is calculated by the following formula (4) when x_{B} is more than 90°

$${y}_{B} = - 0.00012389 {x}_{B}^{2} + 0.00659698 {x}_{B} + 0.99721254 \qquad ( 3 )$$

$${y}_{B} = - 0.00005 \; 913 {x}_{B}^{2} + 0.01099778 {x}_{B} - 0.26784922 \qquad ( 4 )$$

The thickness t₁ of the first film tends to be larger than the thickness t₂ of the second film.

Specifically, when the angle θ formed between the first deposition surface and the second deposition surface is 90°, the t₁/t₂ ratio, which is a ratio of the thickness t₁ (unit: μm) of the first film to the thickness t₂ (unit: μm) of the second film, is preferably 1.5 or more, and more preferably 1.6 or more.

On the other hand, in this case, the t₁/t₂ ratio is, for example, 3.5 or less, and preferably 3.0 or less.

When the angle θ formed between the first deposition surface and the second deposition surface is 90°, the surface (the surface 7c in FIG. 6) of the substrate opposite to the second deposition surface also serves as the second deposition surface, and the second film (yttrium-based protective film) may be formed.

In this case, the t₁/t₂ ratio is larger, and specifically, is preferably 2.0 or more, more preferably 3.0 or more, and still more preferably 4.0 or more. On the other hand, in this case, the t₁/t₂ ratio is, for example, 6.0 or less, and preferably 5.5 or less.

### <<Crystallite Size of Yttrium-Based Protective Film

The crystallite size S₂ of the second film is preferably within a range of 40% of y_{C} times a crystallite size S₁ of the first film, more preferably within a range of 30% thereof, and still more preferably within a range of 20% thereof.

Here, y_{C} is calculated by the following formula (5) when the angle θ formed between the first deposition surface and the second deposition surface is defined as xc of 0° to 170°.

$${y}_{C} = 0.00009729 {x}_{C}^{2} - 0.00273425 {x}_{C} + 0.99976959 \qquad ( 5 )$$

The crystallite size S₁ of the first film tends to be smaller than the crystallite size S₂ of the second film.

Specifically, when the angle θ formed between the first deposition surface and the second deposition surface is 90°, the S₁/S₂ ratio, which is a ratio of the crystallite size S₁ (unit: nm) of the first film to the crystallite size S₂ (unit: nm) of the second film, is preferably 0.90 or less, more preferably 0.80 or less, and still more preferably 0.70 or less.

On the other hand, in this case, the S₁/S₂ ratio is, for example, 0.35 or more, and preferably 0.45 or more.

In this case, the crystallite size S₁ of the first film is preferably less than 20 nm, more preferably less than 18 nm, and still more preferably less than 15 nm. The crystallite size S₂ of the second film is preferably 15 nm or more, more preferably 17 nm or more, and still more preferably 18 nm or more.

### EXAMPLES

Hereinafter, the present invention is specifically described with reference to Examples. However, the present invention is not limited to Examples described below.

Hereinafter, Examples 1 to 21 are Inventive Examples, and Examples 22 to 24 are Comparative Examples.

### Examples 1 to 24

Members each including an yttrium-based protective film were produced under the conditions shown in the following Tables 1 to 3 using the apparatus described based on FIG. 5.

As a substrate, a plate-shaped substrate having deposition surfaces (a first deposition surface and a second deposition surface) with values shown in the following Tables 1 to 3 was used. More specifically, a substrate bent in the middle of a longitudinal direction and thus having a first deposition surface (length: 100 mm) and a second deposition surface (length: 100 mm) was used. The angle (unit: °) of the angle θ formed between the first deposition surface and the second deposition surface is shown in the following Tables 1 to 3.

The substrate was preheated in an air atmosphere while being held by a holder in a chamber. The preheating temperature was 550° C., and the preheating time was 600 minutes.

Next, under the production conditions shown in the following Tables 1 to 3, a base layer and an yttrium-based protective film (a first film and a second film) shown in the following Tables 1 to 3 were formed on the deposition surfaces (the first deposition surface and the second deposition surface) of the substrate using the IAD method.

The second film in Example 5 means an yttrium-based protective film (second film) formed on a surface (surface corresponding to the surface 7c in FIG. 6) opposite to the second deposition surface connected to the first deposition surface. Therefore, “back surface” was indicated in the “angle” column under “deposition surface” in the following Tables 1 to 3.

When the base layer was not formed, “-” was indicated in the corresponding column of the following Tables 1 to 3.

When forming the yttrium-based protective film, argon (Ar) ions and oxygen (O) ions were irradiated from an ion gun toward the substrate at an Ar/O ratio shown in the following Tables 1 to 3.

When forming the base layer, only oxygen (O) ions were irradiated from an ion gun.

As production conditions not described in the following Tables 1 to 3, the distance between the ion gun and the substrate was 1100 mm, and the ion beam current value was 2000 mA.

The compositions of the base layer and the yttrium-based protective film are shown in the following Tables 1 to 3.

In the case where the yttrium-based protective film containing yttrium oxides was formed, “Y₂O₃” is indicated as the composition in the following Tables 1 to 3.

In the case where the yttrium-based protective film containing yttrium oxyfluorides was formed, the composition obtained from the content of each element (Y, O, F, etc.) is indicated as the composition in the following Tables 1 to 3.

In Example 13, one surface side of an aluminum (Al) substrate was subjected to alumite treatment to form a base layer made of Al₂O₃. This base layer is indicated as “alumite” in the following Tables 1 to 3.

In addition, for the base layer and the yttrium-based protective film, the items (Ar content and the like) shown in the following Tables 1 to 3 were determined by the above-described method. Results are shown in the following Tables 1 to 3.

The compressive stress is indicated by a negative numerical value.

For the yttrium-based protective film (first film and second film), the values shown in the following Tables 1 to 3 are the values of the first film unless otherwise specified.

The composition of the second film was the same as that of the first film.

### <Etching Amount>

The yttrium-based protective film of each example was subjected to ion etching to evaluate plasma resistance thereof.

Specifically, first, a surface of 10 mm×5 mm in the yttrium-based protective film was mirror-finished, and a part of the mirror-finished surface (referred to as a “test surface”) was masked with Kapton tape.

Next, using a CCP type plasma etching apparatus, plasma was generated by discharging in a gas under conditions of a pressure of 10 Pa and an RF power of 600 W, and a test (exposure test) of exposing the test surface to the generated plasma was performed.

More specifically, discharge (generation of plasma) was performed using CF₄ gas (flow rate: 100 sccm) and O₂ gas (flow rate: 100 sccm), and ions of CF₄ were generated in the plasma.

The discharge (generation of plasma) for 15 minutes was repeated 10 times, and an exposure test for a total of 150 minutes was performed. Thus, the non-masked portion of the test surface was etched.

Thereafter, the etching amount was determined by measuring a difference between the masked portion and the non-masked portion of the test surface by using a stylus surface profiler (Dectak 150, manufactured by ULLVAC, Inc.). Results are shown in the following Tables 1 to 3.

As the etching amount (unit: nm) is smaller, plasma resistance can be evaluated to be excellent.

TABLE 1

| | | | Example 1 | Example 2 | Example 3 | Example 4 |
|---|---|---|---|---|---|---|
| Production | Internal pressure of chamber [Pa] | | 1 × 10⁻² | 1 × 10⁻² | 1 × 10⁻² | 1 × 10⁻² |
| conditions | Substrate temperature [° C.] | | 300 | 300 | 300 | 300 |
| | Y₂O₃ | Evaporation | 6.78 | 6.78 | 6.78 | 6.78 |
| | YF₃ | source | 8.76 | 8.76 | 8.76 | 8.76 |
| | | deposition rate | | | | |
| | | [nm/min] | | | | |
| | Ar/O ratio | | 6/50 | 6/50 | 6/50 | 6/50 |
| | Ion beam current density [μA/cm²] | | 96 | 96 | 96 | 96 |
| Substrate | Material | | Al₂O₃ | Al₂O₃ | Al₂O₃ | Al₂O₃ |
| | Deposition | Ra [μm] | 0.03 | 0.03 | 0.03 | 0.03 |
| | surface | Area [cm²] | 400.0 | 400.0 | 400.0 | 400.0 |
| | | Angle [°] | 30 | 45 | 60 | 90 |
| Base layer | 1 | Composition | — | — | — | — |
| | | Thickness [μm] | — | — | — | — |
| | 2 | Composition | — | — | — | — |
| | | Thickness [μm] | — | — | — | — |
| | 3 | Composition | — | — | — | — |
| | | Thickness [μm] | — | — | — | — |
| Yttrium- | Composition | | Y₅O_{4.0}F_{6.9} | Y₅O_{4.0}F_{6.9} | Y₅O_{4.0}F_{6.9} | Y₅O_{4.0}F_{6.9} |
| based | Content | Y [atom %] | 31.5 | 31.6 | 31.5 | 31.7 |
| protective | | O [atom %] | 25.0 | 24.9 | 25.0 | 24.9 |
| film | | F [atom %] | 43.5 | 43.5 | 43.5 | 43.4 |
| | F/O ratio | | 1.74 | 1.75 | 1.74 | 1.74 |
| | Ar Content [atom %] | | 0.24 | 0.24 | 0.23 | 0.23 |
| | Peak intensity | First film | 97.2 | 97.3 | 97.6 | 98.1 |
| | ratio [%] | Second film | 98.2 | 86.5 | 66.4 | 48.3 |
| | Vickers | First film (HV₁) | 10.90 | 10.89 | 10.86 | 10.85 |
| | hardness [GPa] | Second film (HV₂) | 13.00 | 10.30 | 7.60 | 7.30 |
| | Young's | First film | 138.44 | 138.47 | 139.23 | 137.76 |
| | modulus [GPa] | Second film | 140.53 | 134.09 | 123.13 | 101.29 |
| | Young's | First film | 12.7 | 12.7 | 12.8 | 12.7 |
| | modulus/Vickers | Second film | 10.8 | 13.0 | 16.2 | 13.9 |
| | hardness | | | | | |
| | Crystallite size | First film (S₁) | 12.4 | 12.3 | 12.4 | 12.3 |
| | [nm] | Second film (S₂) | 12.8 | 12.4 | 15.4 | 19.0 |
| | Thickness [μm] | First film (t₁) | 4.1 | 4.1 | 4.1 | 4.1 |
| | | Second film (t₂) | 4.4 | 4.3 | 3.9 | 2.4 |
| | Porosity [volume %] | | 0 | 0 | 0 | 0 |
| | Half width [°] of rocking curve | | 9.9 | 10.1 | 10.1 | 9.9 |
| | Degree of orientation [%] | | — | — | — | — |
| | Compressive stress [MPa] | | −1503 | −1478 | −1487 | −1479 |
| | Etching amount [nm] | | 73 | 75 | 76 | 73 |
| | | | Example 5 | Example 6 | Example 7 | Example 8 |
| Production | Internal pressure of chamber [Pa] | | 1 × 10⁻² | 1 × 10⁻² | 1 × 10⁻² | 1 × 10⁻² |
| conditions | Substrate temperature [° C.] | | 300 | 300 | 300 | 300 |
| | Y₂O₃ | Evaporation | 6.78 | 6.78 | 6.78 | 6.78 |
| | YF₃ | source deposition | 8.76 | 8.76 | 8.76 | 8.76 |
| | | rate [nm/min] | | | | |
| | Ar/O ratio | | 6/50 | 6/50 | 6/50 | 6/50 |
| | Ion beam current density [μA/cm²] | | 96 | 96 | 96 | 96 |
| Substrate | Material | | Al₂O₃ | Al₂O₃ | Al₂O₃ | Al₂O₃ |
| | Deposition | Ra [μm] | 0.03 | 0.03 | 0.03 | 0.03 |
| | surface | Area [cm²] | 400.0 | 400.0 | 400.0 | 400.0 |
| | | Angle [°] | 90 (back | 120 | 135 | 150 |
| | | | surface) | | | |
| Base layer | 1 | Composition | — | — | — | — |
| | | Thickness [μm] | — | — | — | — |
| | 2 | Composition | — | — | — | — |
| | | Thickness [μm] | — | — | — | — |
| | 3 | Composition | — | — | — | — |
| | | Thickness [μm] | — | — | — | — |
| Yttrium- | Composition | | Y₅O_{4.0}F_{6.9} | Y₅O_{4.0}F_{6.9} | Y₅O_{4.0}F_{6.9} | Y₅O_{4.0}F_{6.9} |
| based | Content | Y [atom %] | 31.5 | 31.5 | 31.8 | 31.1 |
| protective | | O [atom %] | 25.2 | 25.4 | 25.1 | 25.6 |
| film | | F [atom %] | 43.3 | 43.3 | 43.1 | 43.3 |
| | F/O ratio | | 1.72 | 1.70 | 1.72 | 1.69 |
| | Ar Content [atom %] | | 0.25 | 0.23 | 0.23 | 0.25 |
| | Peak intensity | First film | 97.4 | 98.1 | 96.6 | 97.3 |
| | ratio [%] | Second film | — | — | — | — |
| | Vickers | First film (HV₁) | 10.91 | 10.96 | 10.87 | 10.85 |
| | hardness [GPa] | Second film (HV₂) | — | — | — | — |
| | Young's | First film | 138.23 | 137.34 | 138.54 | 138.78 |
| | modulus [GPa] | Second film | — | — | — | — |
| | Young's | First film | 12.7 | 12.5 | 12.7 | 12.8 |
| | modulus/Vickers | Second film | — | — | — | — |
| | hardness | | | | | |
| | Crystallite size | First film (S₁) | — | — | — | — |
| | [nm] | Second film (S₂) | — | — | — | — |
| | Thickness [μm] | First film (t₁) | 4.1 | 4.1 | 4.1 | 4.1 |
| | | Second film (t₂) | 1.0 | 0.8 | 0.6 | 0.2 |

| | | | | |
|---|---|---|---|---|
| Porosity [volume %] | 0 | 0 | 0 | 0 |
| Half width [°] of rocking curve | 10.2 | 10.2 | 9.8 | 9.9 |
| Degree of orientation [%] | — | — | — | — |
| Compressive stress [MPa] | −1504 | −1501 | −1503 | −1473 |
| Etching amount [nm] | 73 | 71 | 78 | 76 |

TABLE 2

| | | | Example 9 | Example 10 | Example 11 | Example 12 |
|---|---|---|---|---|---|---|
| Production | Internal pressure of chamber [Pa] | | 1 × 10⁻² | 1 × 10⁻² | 1 × 10⁻² | 1 × 10⁻² |
| conditions | Substrate temperature [° C.] | | 300 | 300 | 300 | 300 |
| | Y₂O₃ | Evaporation source | 3.42 | 1.92 | 7.24 | 3.42 |
| | YF₃ | deposition rate | 11.88 | 13.36 | 8.13 | 11.88 |
| | | [nm/min] | | | | |
| | Ar/O ratio | | 6/50 | 6/50 | 6/50 | 6/50 |
| | Ion beam current density [μA/cm²] | | 96 | 96 | 96 | 96 |
| Substrate | Material | | Al₂O₃ | Al₂O₃ | Al₂O₃ | Al |
| | Deposition | Ra [μm] | 0.03 | 0.03 | 0.03 | 0.88 |
| | surface | Area [cm²] | 400.0 | 400.0 | 400.0 | 400.0 |
| | | Angle [°] | 90 | 90 | 90 | 90 |
| Base layer | 1 | Composition | — | — | — | Al₂O₃ |
| | | Thickness [μm] | — | — | — | 1 |
| | 2 | Composition | — | — | — | — |
| | | Thickness [μm] | — | — | — | — |
| | 3 | Composition | — | — | — | — |
| | | Thickness [μm] | — | — | — | — |
| Yttrium- | Composition | | Y₅O_{4.2}F_{9.1} | Y₅O_{4.3}F_{9.6} | Y₅O_{4.5}F_{6.2} | Y₅O_{4.0}F_{6.9} |
| based | Content | Y [atom %] | 27.2 | 26.5 | 31.87 | 31.9 |
| protective | | O [atom %] | 23.1 | 22.7 | 28.43 | 24.9 |
| film | | F [atom %] | 49.7 | 50.8 | 39.7 | 43.2 |
| | F/O ratio | | 2.15 | 2.24 | 1.40 | 1.73 |
| | Ar Content [atom %] | | 0.24 | 0.23 | 0.24 | 0.24 |
| | Peak intensity | First film | 97.2 | 95.4 | 71.4 | 91.1 |
| | ratio [%] | Second film | 46.3 | 43.2 | 37.1 | 45.1 |
| | Vickers | First film (HV₁) | 10.61 | 8.76 | 10.60 | 10.89 |
| | hardness | Second film (HV₂) | 7.18 | 5.93 | 7.01 | 7.32 |
| | [GPa] | | | | | |
| | Young's | First film | 128.76 | 115.21 | 122.34 | 136.11 |
| | modulus [GPa] | Second film | 99.92 | 82.34 | 95.23 | 98.99 |
| | Young's | First film | 12.1 | 13.2 | 11.5 | 12.5 |
| | modulus/Vickers | Second film | 13.9 | 13.9 | 13.6 | 13.5 |
| | hardness | | | | | |
| | Crystallite size | First film (S₁) | 12.5 | 11 | 6.1 | 12.3 |
| | [nm] | Second film (S₂) | 19.0 | 16.3 | 9.7 | 18.9 |
| | Thickness [μm] | First film (t₁) | 4.3 | 4.3 | 4.1 | 4.4 |
| | | Second film (t₂) | 2.6 | 2.7 | 2.4 | 2.6 |
| | Porosity [volume %] | | 0.10 | 0.14 | 0.27 | 0 |
| | Half width [°] of rocking curve | | 19.9 | 15.1 | 24.5 | 16.7 |
| | Degree of orientation [%] | | — | — | — | — |
| | Compressive stress [MPa] | | −1318 | −1307 | −1319 | −1375 |
| | Etching amount [nm] | | 73 | 97 | 98 | 93 |
| | | | Example 13 | Example 14 | Example 15 | Example 16 |
| Production | Internal pressure of chamber [Pa] | | 1 × 10⁻² | 1 × 10⁻² | 1 × 10⁻² | 1 × 10⁻² |
| conditions | Substrate temperature [° C.] | | 300 | 300 | 300 | 300 |
| | Y₂O₃ | Evaporation source | 6.78 | 3.42 | 6.78 | 3.42 |
| | YF₃ | deposition rate | 8.76 | 11.88 | 8.76 | 11.88 |
| | | [nm/min] | | | | |
| | Ar/O ratio | | 6/50 | 6/50 | 6/50 | 6/50 |
| | Ion beam current density [μA/cm²] | | 96 | 96 | 96 | 96 |
| Substrate | Material | | Al | Quartz | Quartz | Glass |
| | Deposition | Ra [μm] | 2.29 | 0.02 | 0.02 | 0.03 |
| | surface | Area [cm²] | 400.0 | 400.0 | 400.0 | 400.0 |
| | | Angle [°] | 90 | 90 | 90 | 90 |
| Base layer | 1 | Composition | Alumite | SiO₂ | SiO₂ | SiO₂ |
| | | Thickness [μm] | 12 | 0.5 | 0.5 | 0.5 |
| | 2 | Composition | Al₂O₃ | Al₂O₃ + SiO₂ | Al₂O₃ + SiO₂ | Al₂O₃ + SiO₂ |
| | | Thickness [μm] | 1 | 1 | 1 | 1 |
| | 3 | Composition | — | — | — | Al₂O₃ |
| | | Thickness [μm] | — | — | — | 1 |
| Yttrium- | Composition | | Y₅O_{4.0}F_{6.9} | Y₅O_{4.0}F_{6.9} | Y₅O_{4.0}F_{6.9} | Y₅O_{4.0}F_{6.9} |
| based | Content | Y [atom %] | 31.7 | 32.1 | 31.4 | 31.7 |
| protective | | O [atom %] | 24.9 | 24.9 | 24.5 | 24.9 |
| film | | F [atom %] | 43.4 | 43.0 | 44.1 | 43.4 |
| | F/O ratio | | 1.74 | 1.73 | 1.80 | 1.74 |
| | Ar Content [atom %] | | 0.23 | 0.24 | 0.24 | 0.24 |
| | Peak intensity | First film | 80.4 | 97.5 | 97.3 | 97.5 |
| | ratio [%] | Second film | 38.4 | 48.2 | 48.5 | 48.4 |
| | Vickers | First film (HV₁) | 10.90 | 10.86 | 10.90 | 10.93 |
| | hardness | Second film (HV₂) | 7.46 | 7.23 | 7.46 | 7.34 |
| | [GPa] | | | | | |
| | Young's | First film | 131.43 | 133.12 | 130.87 | 131.35 |
| | modulus [GPa] | Second film | 100.45 | 101.76 | 101.48 | 102.22 |
| | Young's | First film | 12.1 | 12.3 | 12.0 | 12.0 |
| | modulus/Vickers | Second film | 13.5 | 14.1 | 13.6 | 13.9 |
| | hardness | | | | | |
| | Crystallite size | First film (S₁) | 12.2 | 12.1 | 12.3 | 12.5 |
| | [nm] | Second film (S₂) | 19.2 | 18.8 | 18.9 | 18.7 |
| | Thickness [μm] | First film (t₁) | 4.3 | 4.3 | 4.2 | 4.1 |
| | | Second film (t₂) | 2.7 | 2.4 | 2.1 | 2.3 |

| | | | | |
|---|---|---|---|---|
| Porosity [volume %] | 0.23 | 0.00 | 0 | 0 |
| Half width [°] of rocking curve | 19.2 | 9.8 | 10.1 | 10.1 |
| Degree of orientation [%] | — | — | — | — |
| Compressive stress [MPa] | −1307 | −1328 | −1321 | −1342 |
| Etching amount [nm] | 83 | 71 | 73 | 84 |

TABLE 3

| | | | Example 17 | Example 18 | Example 19 | Example 20 |
|---|---|---|---|---|---|---|
| Production | Internal pressure of chamber [Pa] | | 1 × 10⁻² | 1 × 10⁻² | 1 × 10⁻² | 1 × 10⁻² |
| conditions | Substrate temperature [° C.] | | 300 | 300 | 300 | 400 |
| | Y₂O₃ | Evaporation source | 6.78 | 6.78 | 6.78 | 3.42 |
| | YF₃ | deposition rate | 8.76 | 8.76 | 8.76 | 0 |
| | | [nm/min] | | | | |
| | Ar/O ratio | | 6/50 | 6/50 | 6/50 | 6/50 |
| | Ion beam current density [μA/cm²] | | 96 | 96 | 96 | 80 |
| Substrate | Material | | AlN | Al₂O₃ | Al₂O₃ | Al₂O₃ |
| | Deposition | Ra [μm] | 0.04 | 0.03 | 0.03 | 0.03 |
| | surface | Area [cm²] | 400.0 | 400.0 | 400.0 | 400.0 |
| | | Angle [°] | 90 | 90 | 90 | 30 |
| Base layer | 1 | Composition | Al₂O₃ | — | — | — |
| | | Thickness [μm] | 1 | — | — | — |
| | 2 | Composition | — | — | — | — |
| | | Thickness [μm] | — | — | — | — |
| | 3 | Composition | — | — | — | — |
| | | Thickness [μm] | — | — | — | — |
| Yttrium- | Composition | | Y₅O_{4.0}F_{6.9} | Y₅O_{4.0}F_{6.9} | Y₅O_{4.0}F_{6.9} | Y₂O₃ |
| based | Content | Y [atom %] | 31.7 | 31.7 | 31.7 | 46.4 |
| protective | | O [atom %] | 25.1 | 24.9 | 24.8 | 53.6 |
| film | | F [atom %] | 43.2 | 43.4 | 43.5 | 0 |
| | F/O ratio | | 1.72 | 1.74 | 1.75 | 0 |
| | Ar Content [atom %] | | 0.23 | 0.24 | 0.23 | 0.51 |
| | Peak | First film | 97.1 | 98.2 | 98.1 | — |
| | intensity | Second film | 48.1 | 47.7 | 48.1 | — |
| | ratio [%] | | | | | |
| | Vickers | First film (HV₁) | 10.98 | 10.77 | 10.82 | 12.67 |
| | hardness | Second film (HV₂) | 7.46 | 7.27 | 7.40 | 11.38 |
| | GPa] | | | | | |
| | Young's | First film | 137.65 | 124.33 | 139.68 | 172.41 |
| | modulus | Second film | 102.43 | 101.34 | 100.95 | 160.19 |
| | GPa] | | | | | |
| | Young's | First film | 12.5 | 11.5 | 12.9 | 13.6 |
| | modulus/Vickers | Second film | 13.7 | 13.9 | 13.6 | 14.1 |
| | hardness | | | | | |
| | Crystallite | First film (S₁) | 12.5 | 12.3 | 12.3 | 12.1 |
| | size [nm] | Second film (S₂) | 18.6 | 19.0 | 19.1 | 12.5 |
| | Thickness | First film (t₁) | 4.1 | 1.3 | 10.1 | 10.1 |
| | [μm] | Second film (t₂) | 2.3 | 0.73 | 6.2 | 9.8 |
| | Porosity [volume %] | | 0 | 0 | 0 | 0 |
| | Half width [°] of rocking curve | | 11.2 | 9.9 | 9.8 | — |
| | Degree of orientation [%] | | — | — | — | — |
| | Compressive stress [MPa] | | −1387 | −1479 | −1479 | −1242 |
| | Etching amount (nm] | | 72 | 73 | 73 | 93.4 |
| | | | Example 21 | Example 22 | Example 23 | Example 24 |
| Production | Internal pressure of chamber [Pa] | | 1 × 10⁻² | 7 × 10−2 | 1 × 10⁻² | 1 × 10⁻² |
| conditions | Substrate temperature [° C.] | | 400 | 300 | 300 | 300 |
| | Y₂O₃ | Evaporation source | 3.42 | 3.42 | 6.78 | 6.78 |
| | YF₃ | deposition rate | 0 | 11.88 | 8.76 | 8.76 |
| | | [nm/min] | | | | |
| | Ar/O ratio | | 6/50 | 6/50 | 2/50 | 0/50 |
| | Ion beam current density [μA/cm²] | | 80 | 96 | 96 | 96 |
| Substrate | Material | | Al₂O₃ | Al₂O₃ | Al₂O₃ | Al₂O₃ |
| | Deposition | Ra [μm] | 0.03 | 0.03 | 0.03 | 0.03 |
| | surface | Area [cm²] | 400.0 | 400.0 | 400.0 | 400.0 |
| | | Angle [°] | 90 | 90 | 30 | 90 |
| Base layer | 1 | Composition | — | Al₂O₃ | — | — |
| | | Thickness [μm] | — | 1 | — | — |
| | 2 | Composition | — | — | — | — |
| | | Thickness [μm] | — | — | — | — |
| | 3 | Composition | — | — | — | — |
| | | Thickness [μm] | — | — | — | — |
| Yttrium- | Composition | | Y₂O₃ | Y₅O_{4.0}F_{6.9} | Y₅O_{4.0}F_{6.9} | Y₅O_{4.0}F_{6.9} |
| based | Content | Y [atom %] | 46.5 | 27.9 | 31.6 | 31.7 |
| protective | | O [atom %] | 53.5 | 22.4 | 25.5 | 26.1 |
| film | | F [atom %] | 0 | 49.7 | 42.9 | 42.2 |
| | F/O ratio | | 0 | 2.22 | 1.68 | 1.62 |
| | Ar Content [atom %] | | 0.50 | 0.20 | 0.07 | 0.00 |
| | Peak | First film | — | 90.5 | 95.3 | 96 |
| | intensity | Second film | — | 43.3 | 96.2 | 46.4 |
| | ratio [%] | | | | | |
| | Vickers | First film (HV₁) | 12.83 | 5.86 | 8.47 | 8.22 |
| | hardness | Second film (HV₂) | 4.45 | 3.23 | 8.75 | 4.35 |
| | [GPa] | | | | | |
| | Young's | First film | 171.56 | 97.1 | 98.9 | 97.1 |
| | modulus | Second film | 98.79 | 61.6 | 75.3 | 69.6 |
| | [GPa] | | | | | |
| | Young's | First film | 13.4 | 16.6 | 11.7 | 11.8 |
| | modulus/Vickers | Second film | 22.2 | 19.1 | 8.6 | 16.0 |
| | hardness | | | | | |
| | Crystallite | First film (S₁) | 11.8 | 6.3 | 10.2 | 9.8 |
| | size [nm] | Second film (S₂) | 17.9 | 9.9 | 10.8 | 15.1 |
| | Thickness | First film (t₁) | 9.9 | 5.4 | 4.3 | 4.2 |
| | [μm] | Second film (t₂) | 6.2 | 2.9 | 4.1 | 2.2 |

| | | | | |
|---|---|---|---|---|
| Porosity [volume %] | 0 | 1.66 | 0 | 0 |
| Half width [°] of rocking curve | — | 40.1 | 12.3 | 14.2 |
| Degree of orientation [%] | — | — | — | — |
| Compressive stress [MPa] | −1259 | −1247 | −1387 | −1365 |
| Etching amount [nm] | 93.6 | 169 | 102 | 106 |

### Conclusion of Evaluation Results

As shown in the above Tables 1 to 3, it was found that the etching amount of the yttrium-based protective film (first film) was smaller and the plasma resistance was better in Examples 1 to 21 than in Examples 22 to 24.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2023-184119) filed on Oct. 26, 2023, the content of which is incorporated herein by reference.

### REFERENCE SIGNS LIST

1, 2, 3: base layer
4: yttrium-based protective film
5: substrate
6: member
7: deposition surface
7a: first deposition surface
7b: second deposition surface
7c: surface
11: chamber
12, 13: crucible
14: ion gun
15: heater
16: supporting shaft
17: holder
18, 19: quartz crystal film thickness monitor

What is claimed is:

1. An yttrium-based protective film having a porosity of less than 1.5 volume %, a Young's modulus of 100.00 GPa or more, and a Vickers hardness of 8.50 GPa or more.

2. The yttrium-based protective film according to claim 1, wherein a ratio Young's modulus/Vickers hardness is 16.5 or less.

3. The yttrium-based protective film according to claim 1, comprising 0.10 atom % to 3.00 atom % of argon.

4. The yttrium-based protective film according to claim 1, comprising 5 atom % or more of yttrium.

5. The yttrium-based protective film according to claim 1, comprising 25 atom % to 65 atom % of fluorine.

6. The yttrium-based protective film according to claim 1, wherein a F/O ratio, which is a ratio of a fluorine content to an oxygen content, is less than 2.80,
wherein units of the fluorine content and the oxygen content are both atom %.

7. The yttrium-based protective film according to claim 1, wherein a peak intensity ratio of Y₅O₄F₇ in an X-ray diffraction pattern is 60% or more.

8. The yttrium-based protective film according to claim 1, having a crystallite size of 5 nm to 30 nm.

9. The yttrium-based protective film according to claim 1, having a thickness of 0.01 μm to 30.0 μm.

10. A member comprising a substrate and the yttrium-based protective film according to claim 1.

11. The member according to claim 10,
wherein the substrate comprises, as a deposition surface, at least a first deposition surface and a second deposition surface different from the first deposition surface,
a first film that is the yttrium-based protective film is formed on the first deposition surface, and
a second film that is an yttrium-based protective film different from the first film is formed on the second deposition surface.

12. The member according to claim 11, wherein a Vickers hardness HV₂ of the second film is within a range of 40% of y_{A} times a Vickers hardness HV₁ of the first film,
wherein when an angle formed between the first deposition surface and the second deposition surface is defined as x_{A} of 0° to 90°, y_{A} is calculated by the following formula (1) when x_{A} is 0° to 60°, and is calculated by the following formula (2) when x_{A} is more than 60°
$${y}_{A} = - 0.00034 \; 751 {x}_{A}^{2} + 0.01538782 {x}_{A} + 1.00625521 \qquad ( 1 )$$
$${y}_{A} = - 0.0019 \; 7743 {x}_{A} + 0.75229358 . \qquad ( 2 )$$

13. The member according to claim 11, wherein a thickness t₂ of the second film is within a range of 40% of y_{D} times a thickness t₁ of the first film,
wherein when an angle formed between the first deposition surface and the second deposition surface is defined as x_{B} of 0° to 170°, y_{B} is calculated by the following formula (3) when x_{B} is 0° to 90°, and is calculated by the following formula (4) when x_{B} is more than 90°
$${y}_{B} = - 0.00012 \; 389 {x}_{B}^{2} + 0.00659698 {x}_{B} + 0.997 \; 21254 \qquad ( 3 )$$
$${y}_{B} = - 0.00005 \; 913 {x}_{B}^{2} + 0.01099778 {x}_{B} - 0.26784922 . \qquad ( 4 )$$

14. The member according to claim 11, wherein a crystallite size S₂ of the second film is within a range of ±40% of y_{C} times a crystallite size S₁ of the first film,
wherein when an angle formed between the first deposition surface and the second deposition surface is defined as xc of 0° to 170°, y_{C} is calculated by the following formula (5):
$${y}_{C} = 0.00009729 {x}_{C}^{2} - 0.00273425 {x}_{C} + 0.99976959 . \qquad ( 5 )$$

15. The member according to claim 11, wherein an angle formed between the first deposition surface and the second deposition surface is 10° to 160°.

16. The member according to claim 11,
wherein an angle formed between the first deposition surface and the second deposition surface is 90°, and
an HV₁/HV₂ ratio, which is a ratio of a Vickers hardness HV₁ of the first film to a Vickers hardness HV₂ of the second film, is 1.05 to 2.50.

17. The member according to claim 11,
wherein an angle formed between the first deposition surface and the second deposition surface is 90°, and
a t₁/t₂ ratio, which is a ratio of a thickness t₁ of the first film to a thickness t₂ of the second film, is 1.5 to 3.5,
wherein a unit of the thickness is m.

18. The member according to claim 11,
wherein an angle formed between the first deposition surface and the second deposition surface is 90°, and
a t₁/t₂ ratio, which is a ratio of a thickness t₁ of the first film to a thickness t₂ of the second film, is 2.0 to 6.0,
wherein a unit of the thickness is m.

19. The member according to claim 11,
wherein an angle formed between the first deposition surface and the second deposition surface is 90°, and
an S₁/S₂ ratio, which is a ratio of a crystallite size S₁ of the first film to a crystallite size S₂ of the second film, is 0.35 to 0.90,
wherein a unit of the crystallite size is nm.

20. The member according to claim 19, wherein the crystallite size S₁ of the first film is less than 20 nm.

21. The member according to claim 19, wherein the crystallite size S₂ of the second film is 15 nm or more.

22. The member according to claim 10, wherein a surface roughness of a deposition surface of the substrate is, in terms of an arithmetic average roughness Ra, 0.001 μm to 3.00 μm.

23. The member according to claim 10, wherein the substrate has a porosity of 2.0 volume % or less.

24. The member according to claim 10, wherein the substrate is made of at least one selected from the group consisting of carbon, ceramic, and metal.

25. The member according to claim 24,
wherein the ceramic is at least one selected from the group consisting of glass, quartz, aluminum oxide, aluminum nitride, Si-impregnated silicon carbide, and aluminum oxynitride, and
the metal is at least one selected from the group consisting of aluminum and an alloy comprising aluminum.

26. The member according to claim 10, wherein a deposition surface of the substrate has a maximum length of 30 mm or more.

27. The member according to claim 10, comprising one or more base layers between the substrate and the yttrium-based protective film,
wherein the base layer comprises at least one oxide selected from the group consisting of Al₂O₃, SiO₂, Y₂O₃, MgO, CaO, SrO, BaO, B₂O₃, SnO₂, P₂O₅, Li₂O, Na₂O, K₂O, ZrO₂, La₂O₃, Nd₂O₃, Yb₂O₃, Eu₂O₃, and Gd₂O₃.

28. The member according to claim 10, which is used in a plasma etching apparatus or a plasma CVD apparatus.

29. A method for producing the yttrium-based protective film according to claim 1, the method comprising evaporating an evaporation source and depositing the evaporation source onto a substrate while irradiating with ions of at least one element selected from the group consisting of oxygen, argon, neon, krypton, and xenon from an ion gun in a vacuum,
wherein Y₂O₃ or a combination of Y₂O₃ and YF₃ is used as the evaporation source.

30. The method for producing the yttrium-based protective film according to claim 29, wherein at least argon ions are irradiated from the ion gun toward the substrate.
